(19) United States
(12) Patent Application Publication
(10) Pub. No.: US 2006/0152392 A1
(43) Pub. Date: Jul. 13, 2006

(54) Data transmission between computers

(75) Inventors: Georg Biehler, Nurnberg (DE); Josef Dorr, Allersberg (DE); Joachim Feld, Nurnberg (DE); Herbert Oppmann, Nurnberg (DE)

Correspondence Address: SIEMENS CORPORATION;INTELLECTUAL PROPERTY DEPARTMENT, 170 WOOD AVENUE SOUTH, ISELIN, NJ, 08830, US

(73) Assignee: SIEMENS AKTIENGESELLSCHAFT, Munchen (DE)

(21) Appl. No.: 10/542,566

(22) PCT Filed: Jan. 20, 2003
(86) PCT No.: PCT/DE03/00144

§ 371 Date: Jul. 18, 2005

(51) Int. Cl. H03M 7/00

(52) U.S. Cl. 341/60

(57) ABSTRACT

The invention relates to a method, a system and to a transceiver device for transmitting data via a data transmission device. According to said method, during an establishment phase, information concerning the structure of the data to be transmitted is exchanged between two or more transceiver devices. The structure of the data to be transmitted is then compared between the transceiver devices and if the structures match, the data is transmitted in a productive phase. Upon receipt of the data, the latter is assigned by the receiver to the corresponding structure.

### CROSS REFERENCE TO RELATED APPLICATIONS

This application is the US National Stage of International Application No. PCT/DE2003/000144, filed Jan. 20, 2003 and claims the benefit thereof. The International Application is incorporated by reference herein in its entirety.

### FIELD OF THE INVENTION

The invention relates to a method, a system and to a transceiver device for transmitting data via a data transmission device.

### BACKGROUND OF THE INVENTION

In a world characterized by the flow of large volumes of information, ever more data is transmitted nowadays between computers. As a rule the data is transmitted via networks, with the computers connected to the network being able both to transmit and also to receive data. Data is also increasingly being transmitted between controllers or intelligent field devices nowadays, in the area of automation technology in the industrial field for example. This data is transmitted over bus systems or over an industrial Ethernet.

In such cases the volume of data to be transmitted is increasing and the structure of the information to be transmitted is becoming ever more complex, so that specific data structures with a complex layout have to be transmitted between the computers or the automation components or field devices. It is important here for the consistency of the data structures exchanged between the transmitters and receivers involved to be checked. Similarly an efficient data transmission should naturally be guaranteed.

A method and a device is known from U.S. Pat. No. 6,363,428 for transmitting a connection identification and content data separately over a serial bus network.

### SUMMARY OF THE INVENTION

The object of the present invention is now to specify a method, a system and also a transceiver device which makes it possible to transmit data more efficiently.

The object is achieved by a method for transmission of data between transceivers via a data exchange device, in which, in an establishment phase, information on the structure of the data to be transmitted between the transceiver devices is exchanged, the structure of the data to be transmitted between the transceiver devices is reconciled, the data is sent in a productive phase and assigned to the structure on receipt.

Furthermore the object is achieved by a system for transmission of data between transceiver devices via a data exchange device, with first means for exchange of information on the structure of the data to be transmitted between the transceiver devices in an establishment phase, second means for reconciling the structure of the data to be transmitted between the transceiver devices, third means for transmitting the data in a productive phase and fourth means for assigning the data to the structure after receipt of the data.

Furthermore the object is achieved by a transceiver device for transmission of data via a data exchange device, with first means for exchange of information on the structure of the data to be transmitted with at least one further transceiver device in an establishment phase, second means for reconciling the structure of the data to be transmitted with the further transceiver device, third means for transmitting the data in a productive phase and fourth means for assigning the data to the structure after receipt of the data.

The invention is based on the knowledge that, with the volumes of data to be transmitted nowadays, which as a rule obey a complex data structure, an efficient and also a consistent transmission of data is made possible if the data structure description can be transmitted separately from the actual productive data. In this case for example the data structure which corresponds to the data to be transmitted later is first sent from one transceiver device to the other transceiver device. If the data structure sent corresponds both on the transmitter side and also on the receiver side to a defined form which is accepted by transmitter and receiver, the actual data can be transmitted. The consistency of the structure information can thus be checked in advance. The actual data is subsequently transmitted via the data exchange device. This enables transport of data with full details of the structure information to be avoided, which as a rule would not be efficient. If the data were to be transmitted entirely without detailed structure information however, this could lead to problems in ensuring consistency.

In the system presented here however both items of information, namely the detailed structure information and also the subsequent productive data are transferred. Separating the structure from the actual data however increases the performance of the system and thus achieves more efficient handling of the data transmission. At the receiver the incoming data merely has to be assigned again to the corresponding detailed structure information, so the semantics contained in the data can be directly interpreted accordingly.

The efficiency gain is particularly great with this type of data transmission, if data with a specific structure is frequently exchanged between the transceiver devices. This is the case for example with cyclic data transmission at regular intervals or cyclic transmission when a value changes within a cycle.

A further advantageous embodiment of the invention is characterized in that the data is transmitted over a network. The standard systems currently used for the transmission of data can be used in this manner by employing the method presented here. In the area of industry automation in particular networks are used for data transmission between individual automation components such as controllers or field devices. An example of these types of network is what is known as the industrial Ethernet. Individual automation components connected to the Ethernet can transmit their data in a simple way over the Ethernet to other automation components involved with the aid of the method presented here. This means that it is possible to use an already established network standard within the framework of this advantageous development of the method in accordance with the invention and system.

A further advantageous embodiment of the invention is characterized in that the data is transmitted in the form of data packets. This enables a further increase in efficiency to be achieved for the transmission of structure contents, i.e. of the actual data, since the data can be transmitted in packed form, i.e. compressed and thereby space-saving. With increased incidence of data to be transmitted this inventive embodiment makes it possible to use the available network capacities efficiently without any costly expansion having to be needed to increase the transmission capacities.

A further advantageous embodiment of the invention is characterized in that the structure of the data to be transmitted is predetermined by the sending and/or the receiving transceiver device. This embodiment of the invention is advantageous since there is no need to specify the side, i.e. transmitter or receiver, from which the initiative originates. This allows each subscriber connected to the network, that is each transceiver device, to specify a structure definition and subsequently to transmit the productive data to further recipients. The structure definition is checked by the transceiver devices involved for consistency and, if the data structure is appropriate, a transmission is subsequently undertaken. This embodiment of the invention enables the effort of allocating “rights for definition” of structure information to be avoided. It is thus easy for the method or system presented here to be established.

A further advantageous embodiment of the invention is characterized in that a connection identification is sent between the transceiver devices. If detailed structure information is received by a transceiver device connected to the network and if this transceiver device establishes that the detailed structure information is consistent with the actual structure definition, a response to the transmitted structure information can be sent to the transmitter immediately after the establishing phase. The receiver of the connection identification, that is the original transmitter of the detailed structure information, thus knows that the actual data can now be transmitted, and the productive data is sent jointly with the connection identification. On the basis of this connection identification the receiver can subsequently assign the productive or net data to the corresponding structure definition in a simple manner. This guarantees a consistent and efficient transmission of data.

A further advantageous embodiment of the invention is characterized in that the data is transmitted over an Internet. If the transceiver devices involved are not all connected to an Ethernet or field bus system, but data is transmitted between them, for example with production which is spread over a number of locations, over the Internet, this can also be handled consistently and efficiently within the framework of the inventive system. The advantage here is that not all transceiver devices have to have hardware connections between them. This enables data to be transmitted between a number of locations. This is useful for example if the production processes of different locations are to be visualized on an operation and maintenance system at a central point. A further alternative or additional advantageous embodiment is to use the system in conjunction with a central plant information system, in which the data arising in the production process is administered or archived in a central data memory. Data of the different production sites, covering controllers, field devices, sensors and any other automation components for example can be collected and stored at a central location. In scenarios of this type it is especially advantageous to ensure that data is transmitted efficiently, since with central collection of the information from the production level large volumes of data to be transmitted arise.

The invention is described and explained in more detail below on the basis of an exemplary embodiment.

### BRIEF DESCRIPTION OF THE DRAWING

FIG. 1 shows a system for transmission of data.

### DETAILED DESCRIPTION OF THE INVENTION

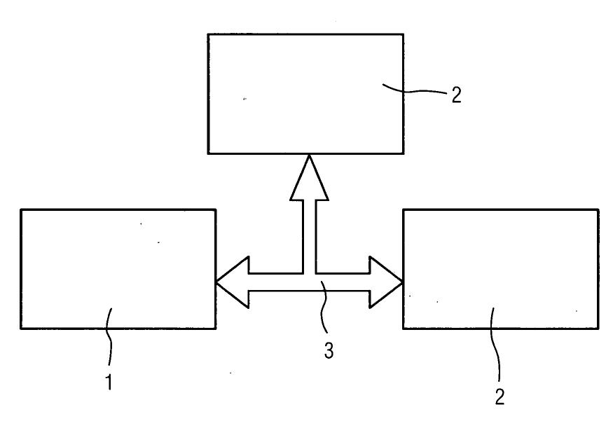

FIG. 1 shows a system in which transceiver devices 1,2 exchange data with each other via a data transmission device 3. The transceiver devices 1,2 can be any given computers. Equally however, in addition or as an alternative, an automation component, for example in an automation system for an industrial production process, can be represented by a corresponding transceiver devices 1,2. In this case the number of transceiver devices 1,2 involved is not limited to the examples shown in FIG. 1. Instead further transceiver devices 1,2 can participate in the data transmission. Detailed structure information is transmitted between the transceiver devices in a first phase of establishing the data transmission. This is information about the actual structure of the data subsequently to be transmitted. At the beginning of the data transmission the detailed structure information is transmitted and the data is reconciled between the transceiver devices 1,2 involved. If the structure definitions match each other, a connection identification is sent as a response to the corresponding request. In the subsequent productive phase the connection identification transmitted is sent together with the net data or productive data to be transmitted. On the basis of the connection identification the receiver of the data can assign the net data or productive data which arrives to a structure definition that it has available. The fact that the data is assigned to the structure again enables the receiver to extract the actual information content from the data again.

With the transmission of data in accordance with the invention the structure definition and the structure content are thus separated for transport over a network. The consistency of the structure definition is reconciled between the transceiver devices 1,2 involved at the start of the data transmission. Consistency is thus guaranteed, but only a single check is made on the consistency of the data at the transceiver devices 1,2 involved. The subsequent net data or productive data is exchanged by an efficient exchange of the contents. In this case, to further increase efficiency, the data can be transmitted in the form of data packets. This results in compression of the data and thus ensures space-saving and time-saving transmission of the data. As well as data transmission over a network, for example an industrial Ethernet, data transmission in the form proposed is also possible over the Internet.

To summarize, the invention relates to a method, a system and also a transceiver device for transmission of data via a data transmission device. In this case information on the structure of the data to be transmitted is exchanged in an establishment phase between two or more transceiver devices. Subsequently the structure of the data to be transmitted is reconciled between the transceiver devices and, if a match is established, the data is sent in a productive phase. On receipt the data is assigned by the receiver to the associated structure.

1.-14. (canceled)

15. A method for transmitting data between transceiver devices via a data exchange device, the method comprising:
exchanging information regarding a structure of the data to be transmitted between the transceiver devices in an establishment phase;
performing a reconciliation of the structure of the data between the transceiver devices;
transmitting the data in a productive phase; and
assigning the data to the structure on receipt.

16. The method in accordance with claim 15, wherein the data is transmitted over a network.

17. The method in accordance with claim 15, wherein the data is transmitted in the form of data packets.

18. The method in accordance with claim 16, wherein the data is transmitted in the form of data packets.

19. The method in accordance with claim 15, wherein the structure of the data to be transmitted is provided by the sending and/or by the receiving transceiver device.

20. The method in accordance with claim 16, wherein the structure of the data to be transmitted is provided by the sending and/or by the receiving transceiver device.

21. The method in accordance with claim 17, wherein the structure of the data to be transmitted is provided by the sending and/or by the receiving transceiver device.

22. The method in accordance with claim 15, wherein a connection identification is transmitted between the transceiver devices.

23. The method in accordance with claim 16, wherein a connection identification is transmitted between the transceiver devices.

24. The method in accordance with claim 15, wherein the data is transmitted via the Internet.

25. A system for transmission of data between transceiver devices via a data exchange device, comprising:
a first mechanism for exchanging information regarding a structure of the data to be transmitted between the transceiver devices in an establishment phase;
a second mechanism for adjusting the structure of the data between the transceiver devices;
a third mechanism for transmitting the data in a productive phase; and
a fourth mechanism for assigning the data to the structure after receiving the data.

26. The system in accordance with claim 25, wherein a network is provided for the transmission of the data.

27. The system in accordance with claim 25, wherein the data is provided for transmission in the form of data packets.

28. The system in accordance with claim 25, wherein a sending and/or a receiving transceiver devices are provided for predetermining the structure of the data to be transmitted.

29. The system in accordance with claim 25, further comprising a fifth mechanism for transmitting a connection identification between the transceiver devices.

30. The system in accordance with claim 25, wherein an Internet is provided for transmission of the data.

31. A transceiver device for transmitting data via a data exchange device, comprising:
a first mechanism for exchanging information regarding a structure of the data to be transmitted with at least one further transceiver device in an establishment phase;
a second mechanism for reconciling the structure of the data to be transmitted with the at least one further transceiver device;
a third mechanism for transmitting the data in a productive phase; and
a fourth mechanism for assigning the data to the structure after receipt of the data.

32. The transceiver device in accordance with claim 31, further comprising:
a fifth mechanism for sending a connection identification to the at least one further transceiver device.
